(19) United States
(12) Patent Application Publication
(10) Pub. No.: US 2006/0192004 A1
(43) Pub. Date: Aug. 31, 2006

(54) Stylized method of using and distributing consumer electronic devices

(76) Inventors: Gidon Elazar, Tsur-Yigal (IL); Dan Harkabi, Moshav Lachish (IL); Nehemiah Weingarten, Ramat-Gan (IL)

Correspondence Address: PARSONS HSUE & DE RUNTZ LLP, 595 MARKET STREET, SUITE 1900, SAN FRANCISCO, CA, 94105, US

(21) Appl. No.: 11/280,527

(22) Filed: Nov. 15, 2005

Related U.S. Application Data
(60) Provisional application No. 60/629,704, filed on Nov. 22, 2004.

(51) Int. Cl. G06F 13/38; H01L 21/336; G06K 7/00

(52) U.S. Cl. 235/435; 710/62; 438/258

(57) ABSTRACT

Various embodiments of a consumer electronic device comprising two components are disclosed. One component is the functional element, another component is a stylized element. In an example of a USB flash drive, a functional component includes flash memory and a controller, while the stylized element is a case with a plug that inserts into a USB receptacle of a personal computer or other electronic device. The more expensive functional component is mass produced in a common form while many different versions of the less expensive stylized element are produced according to varying consumer tastes.

### CROSS REFERENCE TO RELATED APPLICATION

This non-provisional application claims the benefit of provisional application No. 60/629,704, filed Nov. 22, 2004, which application is incorporated herein in its entirety by this reference. This application is also related to an application being filed concurrently herewith by Gidon Elazar et al., entitled “Stylized Consumer Electronic Device.”

### BACKGROUND OF THE INVENTION

The present invention relates to consumer electronic devices and how they can be of higher value to consumers through the use of industrial designs. All patents, patent applications, articles, other documents and things referenced herein are hereby incorporated herein in their entirety for all purposes.

People enjoy variety. The world of fashion enables people to choose from thousands of different kinds of shoes, clothes, watches, sunglasses and the like. Generally all shoes provide the same basic functionality, and the main differentiator to people is the fashion element. The economics of the aforementioned industries lend themselves to fashion lines due to the very low manufacturing costs of the goods themselves. The profit margin on such products are in the hundreds of percents, which leaves wiggle room for experimentation with various new shapes, sizes, colors, and designs. A designer may introduce a new line of 20 sunglass frames for a summer collection. Even though most of the designs won't catch on as the vogue, the few that will become a hit will more than compensate for the bulk that will have to be sold at reduced prices or returned from the stores for destruction. This economic model allows for great creativity and diversity in various products, and new product designs for every new season, to the benefit of the consumer.

In the realm of consumer electronics, the margins on a product are usually much lower. Therefore there is little room for the vendors to invest in multiple fashion elements for their products. A line of products from a specific vendor is usually differentiated by technical specifications and functionality, not so much by fashion.

There are however some consumer electronic devices that have a potential for becoming fashion items. An interesting category within consumer electronics is the USB flash drive. A USB flash drive is a small flash memory based storage device having a connector according to the Universal Serial Bus (USB) standard that may be plugged into the USB port of a personal computer (PC) and serve as a removable storage means. This product was introduced in about 2000, and has since caught on in the world, being sold by many vendors (some references count over 100 vendors or manufacturers), and in 2004 projected at over 40 million units worldwide. An example is a line of flash drives sold by SanDisk Corporation, assignee hereof, under its trademark Cruzer.

The basic functionality of these devices, offered by many vendors, is identical, and so the product category has quickly been commoditized, with most players trying to compete on the lowest price. Some vendors are trying to compete by providing software tools for data management on the USB flash drives. As more and more people will be using these devices in the foreseeable future, there is a large incentive to try to differentiate based on additional parameters.

Since the Flash USB drive is a personal article, and is small enough to fit into a pocket or a purse, it makes sense to try to make it more appealing by offering people a large variety of shapes, sizes, colors, designs, and logos to choose from, very similar to eyeglasses or shoes.

However, the margins for consumer electronics and for USB flash drives are very low when compared to apparels and accessories, and since the risk of manufacturing a varied fashion line that will not be successful is very high, it is currently not economically wise for a vendor to create more than a handful of industrial designs for a USB flash product.

A flash memory card is flash memory commonly encapsulated in a thin, rectangle-like card-shaped plastic shell, which gives the notion of a card, and gives it its name. Examples of flash memory cards are those sold by SanDisk Corporation and others under trademarks and names Secure Digital (SD), mini SD, Trans Flash (T-Flash), extreme Digital (xD), Compact Flash (CF), Memory Stick, Memory Stick Pro, Memory Stick Duo, Smart Media, Multi Media Card (MMC). A flash memory card may be composed of a controller in addition to the flash memory. A flash memory card has an external interface to communicate with a host computing device, such as a computer, a digital camera, PDA or the like, for transfer of data to be stored on or retrieved from the flash memory. The electrical interface and logical protocol interface of the card to the host computing device is a property of the card. For example SD, mini SD, and T-Flash cards have an interface that enables them to communicate using the SD protocol.

Existing art provides means of connecting Flash memory cards to USB. Flash Cards such as Secure Digital (SD) or Trans-Flash (T-Flash) cannot directly connect to a USB connector as their interface has different electrical and/or protocol properties, and their controller interfaces according to an SD or T-Flash protocol. In order for these devices to connect to a USB port there is a need for additional electronic components, for example at least a USB controller, that translates the SD protocol into the USB protocol. An example is the flash card reader available from a number of manufacturers. The additional electronic components are located in the flash card reader and contribute to its manufacturing cost in such a way that the margins are low as with other consumer electronic devices. Thus the possible use of a flash card reader as a fashion element is also not economic.

### SUMMARY OF THE INVENTION

A USB flash drive commonly comprises the following components: Flash memory, a controller, USB connector, and an industrial design shelling. The first two components account for most of the manufacturing costs (sometimes more than 90%) of the flash drive. The shell and USB connector account for a very small percentage of the total manufacturing cost. If the manufacturing process is modified to provide the first two components (flash memory and controller) as one product, preferably in as a single enclosed unit, and the second two components (connector and design shell) as a second, add-on product, then there is more room for a fashion line of USB drives. Many versions of the second product are manufactured with a variety of aesthetic designs.

Existing art does not address the separation of the functional elements of a consumer electronic device from the fashion elements, thereby limiting the variety offered to consumers. This problem is addressed by the present invention, which will be understood by reading the following specification. By physically separating the functional component of a consumer electronic device from the fashion component, each may be manufactured separately, and even sold separately. This way, a consumer may choose from a large variety of industrial designs, according to personal taste, while enjoying the functionality of the consumer electronic device no matter which design was chosen.

### BRIEF DESCRIPTION OF THE DRAWINGS

The foregoing and other objects, aspects, and advantages will be better understood from the following description of an embodiment of the invention with reference to the drawings, wherein:

FIG. 1 is an example of existing art—a USB flash drive.

FIG. 2 is a schematic block diagram of the components of a common exemplary embodiment of a USB flash drive.

FIG. 3 is a schematic block diagram of an exemplary embodiment of functional component of an exemplary embodiment of a Fashion USB flash drive.

FIG. 4 is a schematic block diagram of an exemplary embodiment of fashion component of an exemplary embodiment of a Fashion USB flash drive.

FIG. 5 is a schematic block diagram of an exemplary embodiment of a fashion USB flash drive including a functional component and a fashion component.

### DESCRIPTION OF THE INVENTION

In the following description of exemplary embodiments of the invention, reference is made to the drawings that illustrate specific exemplary embodiments in which the invention may be practiced. Those skilled in the art will appreciate that other embodiments may be utilized without departing from the spirit of the present invention; therefore the following detailed description of the invention should not be taken in a limiting sense. In various embodiments, there may be none, one, or more than one of the following described parts.

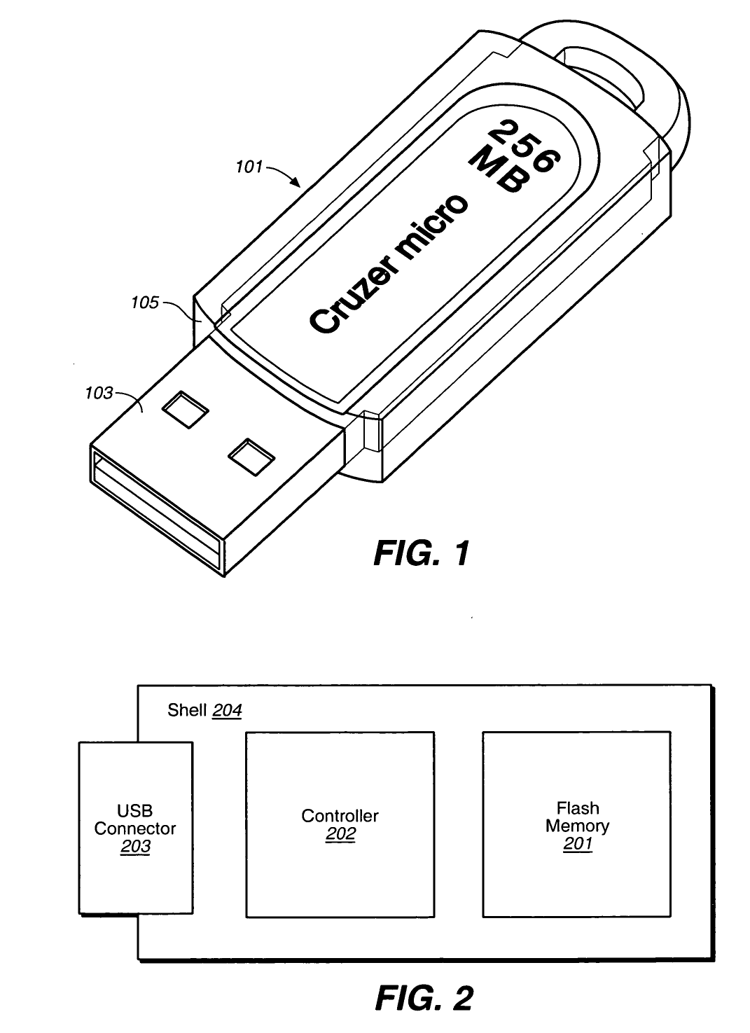

FIG. 1 is an example of existing art—a USB flash drive. The functional components, including flash memory and a memory controller formed on one or more integrated circuits, are embedded within the industrial design, also referred to herein as the “fashion component,” and the manufacturing process churns out unified units, which cannot be readily disassembled by the user, and are not intended for disassembly in normal use. The USB flash drive of FIG. 1 includes a body 101 containing the integrated circuit(s) enclosed in a metal case that also extends beyond the body to form a USB plug 103. A plastic cover 105 is fit over the body portion with a trademark of the product and information of its characteristics.

FIG. 2 is a schematic block diagram of a common embodiment of a USB flash drive.. The components comprise at least a flash memory 201, a controller 202, USB connector 203, and shell 204. The controller 202 can interface with at least the USB connector 203 and the flash memory 201.

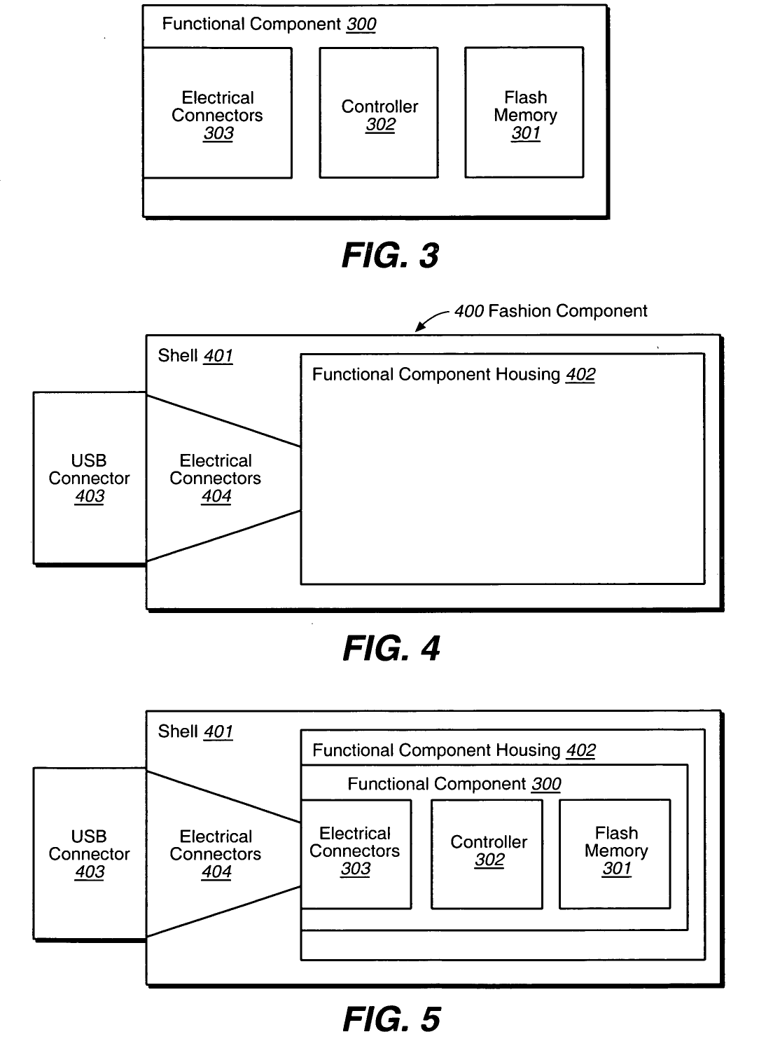

FIG. 3 is a schematic block diagram of the functional component of an exemplary embodiment of a fashion USB flash drive 300. The elements of the functional component comprise a flash memory 301, a controller 302 and electrical connectors 303. The electrical connectors 303 are used for interfacing to at least a USB connector and are able to drive at least the USB protocol.

In some embodiments the elements of the functional component are placed on a PCB (PC Board). In some embodiments, the elements of the functional component are packaged in some shell.

In some embodiments the elements are packaged in a rectangle-like card-shaped shell.

In some embodiments the elements are packaged in a shell that may be used for flash cards such as those sold under one of the trademarks or names Secure Digital (SD), mini SD, T-Flash, extreme Digital (xD), Compact Flash (CF), Memory Stick, Memory Stick Pro, Memory Stick Duo, Smart Media, Multi Media Card (MMC), SIM card and the like; this invention is not so limited.

In some embodiments, the elements are interconnected in some other manner; this invention is not so limited.

In some embodiments additional elements are present in, the functional component; this invention is not so limited.

FIG. 4. is a schematic block diagram of the fashion component 400 of an exemplary embodiment of a fashion USB flash drive, including a shell 401, a functional component housing 402, a USB connector 403, and electrical connectors 404. Housing 402 serves as housing for the functional component of a fashion USB flash drive 300. Electrical connectors 404 serve to send and receive electrical signals from electrical connectors 303 to the USB connector 403.

In some embodiments, housing 402 is a cavity within shell 401, this invention is not so limited.

FIG. 5 is a schematic block diagram of an exemplary embodiment of a fashion USB flash drive. The fashion USB flash drive 500 is comprised of a functional component 300, and a fashion component 400.

In some embodiments, the functional component 300 may be combined into a flash card with a particular interface protocol such as T-Flash interface. The electrical connectors 303 in this case may serve a dual purpose. When functioning as a stand-alone T-Flash flash card, the electrical connectors 303 adhere to the T-Flash protocol; when functioning inside fashion component 400 as a fashion USB flash drive 500, at least part of the electrical connectors adhere to the USB protocol. The controller 302 inside the flash card can identify the electrical voltages and signals it receives upon first interaction with a host device, or identify some mechanical aspect of the card and accordingly choose by which protocol to behave. There is no need for an additional electrical element, such as a controller, in fashion component 400, only electrical connectors 404 to send and receive signals from functional component 300 to the USB connector 403.

In some embodiments the functional component 300 may be a combined with a flash card such as one sold under one of the trademarks or names Secure Digital (SD), mini SD, extreme Digital (xD), Trans Flash (T-flash), Compact Flash (CF), Memory Stick, Memory Stick Pro, Memory Stick Duo, Smart Media, Multi Media Card (MMC), or combined with a SIM card with the SIM card interface, and the likes; this invention is not so limited.

In some embodiments, the fashion USB flash drive is sold to consumers with the functional component housed within the fashion component. An advantage to the manufacturer is that if purchasers do not like a particular fashion component, namely a specific industrial design or outer appearance, and return the product for that reason, the functional components can be retrieved and reused by placing them within other fashion components that look different. Since most of the manufacturing cost of the returned items is in their functional components, their reuse saves the manufacturer a substantial amount of money. The manufacturer may need to discard the fashion components of returned products but their low manufacturing cost relative to that of the functional component makes this feasible.

In some embodiments the functional component and the fashion component are sold separately; this invention is not-so limited. When end users purchase products at a retail store or over the Internet, for example, they may therefore select among a number of fashion components having different appearances that appeal to them. One of the available fashion components is then combined with one of the standard functional components that are all alike. Also, if the user comes to dislike the fashion component of a product that has been purchased, a new fashion component having a different appearance may be purchased at a relatively low cost. In some embodiments, therefore, a consumer may purchase additional fashion components for an existing functional component.

In some embodiments, a consumer may customize his or her fashion component through an online or phone ordering mechanism that relays the customization information to the manufacturing plant.

In some embodiments, the fashion consumer electronic device is an MP3 player. In some embodiments, the fashion consumer electronic device is a multimedia player. In some embodiments, the fashion consumer electronic device is a PDA. In some embodiments, the fashion consumer electronic device is a smartphone. In some embodiments, the fashion consumer electronic device is an ebook reading device. This invention is not so limited.

Although the present invention has been described with reference to particular embodiments, it is not to be construed as being limited thereto. Various alterations and modifications can be made to the embodiments without in any way departing from the scope or spirit of the present invention.

It is claimed:

1. A method of supplying flash drives, comprising:
providing a plurality of substantially identical core units that individually include a flash memory and memory controller,
providing a variety of shells having an integral connector and into which a core unit is insertable, the variety of shells having different outer appearances, and
wherein the cost of manufacturing the core unit is greater than the cost of manufacturing the shell,
whereby the core units may be positioned inside those of the variety of shells that are suitable to individual aesthetic tastes of consumers.

2. The method of claim 1, wherein the cost of manufacturing the core unit is more than ninety percent of the total cost of manufacturing the core unit and shell.

3. The method of claim 1, wherein the core units and shells are sold separately to consumers, whereby the user may pick an aesthetically pleasing shell to combine with the core unit when purchasing a flash drive.

4. The method of claim 1, wherein the core unit is a memory card with the flash memory and memory controller enclosed together.

5. The method of claim 1, wherein the connector includes a USB plug.

6. A method of distributing hand-held memory systems, comprising:
acquiring a plurality of common core memory units,
acquiring a plurality of outer shells having different visual appearances,
distributing memory systems individually formed from one of the common core units and an attached outer shell having one of the different visual appearances,
in response to memory systems being returned because of their visual appearances, removing the shells from the common core units, and
thereafter combining the returned core units with shells having different appearances than those of the returned memory systems.

7. The method of claim 6, wherein the memory system is a flash drive.
